(19) United States
(12) Patent Application Publication
(10) Pub. No.: US 2009/0282313 A1
(43) Pub. Date: Nov. 12, 2009

(54) METHOD AND APPARATUS FOR HARD DECISION BOUNDED DISTANCE DECODING OF NORDSTROM ROBINSON CODE

(75) Inventors: LIN YANG, FREMONT, CA (US); ABHIRAM PRABHAKAR, FREMONT, CA (US)

Correspondence Address: FRANK F. TIAN, 331-4A THIRD AVENUE, LONG BEACH, NJ, 07740, US

(73) Assignee: LEGEND SILICON CORP., FREMONT, CA (US)

(21) Appl. No.: 12/116,931

(22) Filed: May 7, 2008

(51) Int. Cl. H03M 13/03; G06F 11/08

(52) U.S. Cl. 714/752; 714/E11.03

(57) ABSTRACT

A receiver is provided that comprises a decoder. The decoder comprises: means for slicing a signal; means for encoding data/messages to a code word among a predetermined number of code words; and means for determining a distance associated with the code word.

### FIELD OF THE INVENTION

The present invention relates generally to Nordstrom Robinson (NR) code decoders, more specifically the present invention relates to a NR code ASIC decoder having improved architecture for throughput, power, memory and chip area.

### BACKGROUND

The rapid growth of wireless communication systems has led researchers to look for new codes and re-investigate old codes for error control coding. The NR code first published in 1967 by Nordstorm and Robinson (see A. W. Nordstrom and J. P. Robinson, “An Optimum Nonlinear code”, Information control, pp. 284-287, 1967) is a non-linear, systematic, unique code (see S. Snover; “The uniqueness of Nordstrom-Robinson code and the Golay binary code”, Ph.D Dissertation, Michigan State Univ, 1973). The code described in the publication has twice the number of code words of any linear code with the same minimum distance 6 and length 16. Since NR code is non-linear, which required complex decoding algorithms, it has been mostly ignored for the last 3 decades. Recent innovations in the representation of NR code have made NR codes attractive for hardware implementation that is on par with linear codes.

Therefore, hard decision bounded distance decoding of Nordstrom Robinson Code is desirable.

### SUMMARY OF THE INVENTION

The present invention provides an improved architecture for a Nordstrom Robinson Code in a logic and/or memory such that an improved throughput, power consumption and memory area is achieved.

A method for finding a unique code word is provided. The method comprising the steps of: providing a slicer for slicing a signal; providing an encoder to encode data/messages to a code word among a predetermined number of code words; and determining a distance associated with the code word.

A decoder is provided. The decoder comprises: means for slicing a signal; means for encoding data/messages to a code word among a predetermined number of code words; and means for determining a distance associated with the code word.

A receiver is provided that comprises a decoder. The decoder comprises: means for slicing a signal; means for encoding data/messages to a code word among a predetermined number of code words; and means for determining a distance associated with the code word.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of an architecture using a special circuit to find out the C_{unique} in accordance with some embodiments of the invention.

FIG. 2 is an example of a block diagram of a decoder architecture for the NR code in accordance with some embodiments of the invention.

FIG. 3 is an example of an architecture with a parallelization of 4 in accordance with some embodiments of the invention.

FIG. 4 is an example of a first flowchart in accordance with some embodiments of the invention.

FIG. 5 is an example of a second flowchart in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to an improved architecture in the logic and memory such that an improved throughput, power consumption and memory area is achieved. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of relating to a method for an improved architecture in the logic and memory such that an improved throughput, power consumption and memory area is achieved. In the exemplified embodiments, it is noted that the processors include Finite State Machines, which are used in the preferred embodiment. The non-processor circuits may include, but are not limited to, a radio receiver, a radio transmitter, signal drivers, clock circuits, power source circuits, and user input devices. As such, these functions may be interpreted as steps of a method for combining equalized information from a first path and a second path. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Nordstrom Robinson (NR) code is a rate half non-linear, systematic, unique code with minimum distance 6 and code word length 16. There are a total of 256 code words in the code set. The code is non-linear since the binary addition of two code words does not produce another code word. There are many constructions of the Nordstrom Robinson code which are equivalent under permutation of the 16 components (16 bits) and hence the NR code is unique.

The NR code can be constructed in many ways, but all the resulting codes are equivalent to one another. One representation where the non-linear NR code in binary field is presented as a linear code over Z4 (i.e. the integers mod 4) that can be found in R. Klein, M. Varanasi and L. Dunning, “Multiple error detection/correction using the Nordstrom-Robinson code”, Proceedings of the 43^{rd} IEEE Midwest symposium on circuits and systems 2000. vol 1, pp: 254-257, which is hereby incorporated herein by reference. Another method of representation using Hadamard-Sylvester matrix and its decoding algorithm can be found in J.-P. Adoul, “Fast ML Decoding Algorithm for the Nordstrom-Robinson Code”, IEEE trans on Information Theory, vol. IT-33, pp 931-933, 1987, which is hereby incorporated herein by reference. A representation of NR code over GF(4) and an efficient decoding algorithm for it can be found in A. Vardy, “The Nordstrom-Robinson Code:Representation over GF(4) and Efficient decoding”, vol 40, issue 5, pp: 1686-93, September 1994, which is hereby incorporated herein by reference.

The present invention focuses upon an embodiment of the NR codes used in the Chinese DTV standard otherwise known as GB 20600-2006, relating to “Framing Structure, Channel Coding and Modulation for Digital Television Terrestrial Broadcasting System”.

The encoding of message bits to NR code words can be represented by a set of parity check equations under the following conditions. Let: the 8 message bits be represented by x0 x1 x2 x3 x4 x5 x6 x7, and let the 8 parity bits to be derived be y0 y1 y2 y3 y4 y5 y6 y7; Then: the 16 bit binary NR code word is given by: [x0 x1 x2 x3 x4 x5 x6 x7 y0 y1 y2 y3 y4 y5 y6 y7]. The parity bits are derived according to the following equations:

y0=x7+x6+x0+x1+x3+(x0+x4)(x1+x2+x3+x5)+(x1+x2) (x3+x5)

y1=x7+x0+x1+x2+x4+(x1+x5)(x2+x3+x4+x6)+(x2+x3) (x4+x6)

y2=x7+x1+x2+x3+x5+(x2+x6)(x3+x4+x5+x0)+(x3+x4) (x5+x0)

y3=x7+x2+x3+x4+x6+(x3+x0)(x4+x5+x6+x1)+(x4+x5) (x6+x1)

y4=x7+x3+x4+x5+x0+(x4+x1)(x5+x6+x0+x2)+(x5+x6) (x0+x2)

y5=x7+x4+x5+x6+x1+(x5+x2)(x6+x0+x1+x3)+(x6+x0) (x1+x3)

y6=x7+x5+x6+x0+x2+(x6+x3)(x0+x1+x2+x4)+(x0+x1) (x2+x4)

y7=x0+x1+x2+x3+x4+x5+x6+x7+y0+y1+y2+y3+y4+y5+y6

Here the “+” operand represents binary addition.

During the transmission the transmitted code word gets corrupted with noise. Let the received code word R at the receiver be represented as,

R=[r15, r14, r13 . . . r2, r1, r0].

Here R15 . . . r0 being real numbers (soft values). A hard decision represents or is operatively defined as slicing of the received numbers to binary values 0 and 1 (i.e. hard values).

The hard decision input at the receiver is given by:

H=[h15, h14 . . . h1, h0].

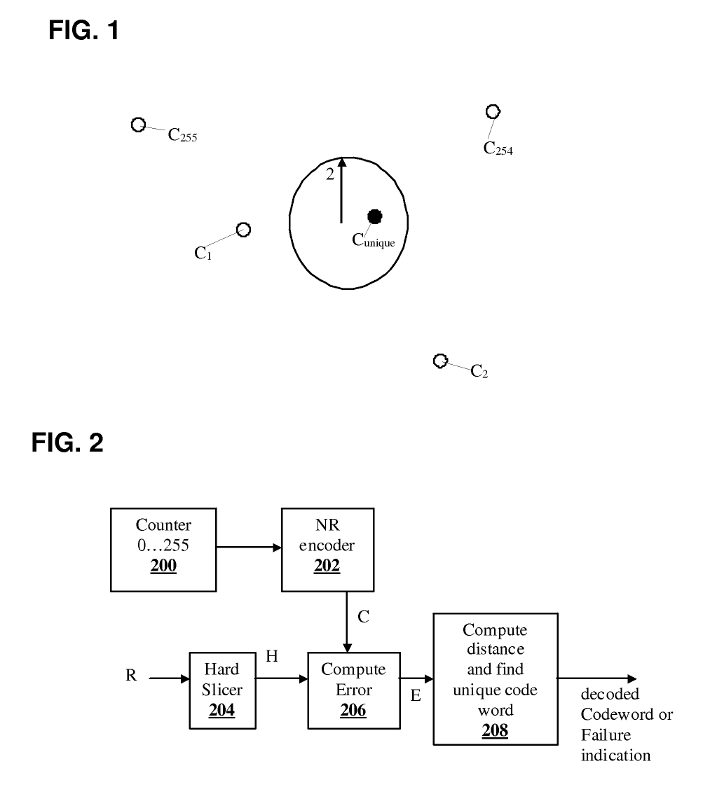

The distance between two code words is defined by the number of positions in which the binary bits differ. Any binary code with minimum distance dₘᵢₙ, can correct upto (dₘᵢₙ−½) errors. Therefore, the NR code can correct up to 2 errors. This is due to the fact that there is only one code word at distance 2 or less from the received word H. This fact is used in the decoder architecture to find the unique code word C_{unique} that is at a distance 2 or less from the received word. If no code word is found within distance 2 from the received word, a decoder failure is declared. Such a decoder is called bounded distance decoder. This is illustrated in FIG. 1 infra.

Referring to FIG. 1, an architecture using a special circuit to find out the C_{unique} is shown. In our architecture a special circuit to find out the C_{unique} is used. As can be seen, the C_{unique} is the only code word within the dₘᵢₙ equal to 2.

FIG. 2 a block diagram of a decoder architecture for the NR code. Since there are 256 code words one has to compare the received code word with each of these code words to find the unique code word that is at a distance of less than or equal to 2. A counter 200 generates the messages 0 . . . 255 and the NR code words are obtained using an encoder 202. Errors are computed respectively 206. In our preferred embodiment, the bits in error are found using simple XOR gates. Let the error word be given by:

E=[e15, e14 . . . , e3, e2, e1, e0].

The computations of E are as follows:

E=[h15̂c15, h14̂c14, . . . h1̂c1, h0̂c0]=[e15, e14, . . . , e3, e2, e1, e0].

The error word E is given to the special circuit (not shown) to find the code word at distance 2 or less. Skilled artisans can design a circuit based on supra with substantially no experimentations. It should be noted that H (hard sliced information) is computed only once per received NR code word.

The special circuit counts the distance of the received word (i.e. the number of 1's in E). Since there should be only one code word having distance 2 or less from the received word, there is no need to actually count the exact distance of each code word from the received word. One simply identifies the code words at a distance greater than or equal to 3 and drop such code words. Since only one code word may not satisfy this condition, that one code word is identified and given as output. If all the code words are at distance 3 or greater, a decoder failure is declared.

The logic used for counting operation is given by:

e0+e1+e2=c0s0

e3+e4+e5=c1s1

e6+e7+e8=c2s2

e9+e10+e11=c3s3

e12+e13+e14=c4s4;

c0s0+c1s1=x2x1x0

c2s2+c3s3=y2y1y0

x1x0+y1y0=z2z1z0

z1z0+c4s4=w2w1w0;

a1=w1&w0;

a2=w1&e15;

code_valid=˜(x2|y2|z2|w2|a1|a2);

code_valid=1: Found a valid code word

code_valid=0: Decoder failure;

where:

+: Addition

&: bit and operation

|: bit or operation

˜: bit inversion

x2,y2,z2,w2 indicate if there are more than 3 errors in E. a1 and a2 indicate if there are exactly 3 errors in E. If none of them are true then we have only 2 or less errors in E and hence the code word is the unique decoded output. Skilled artisans can design a circuit based on supra with substantially no experimentations.

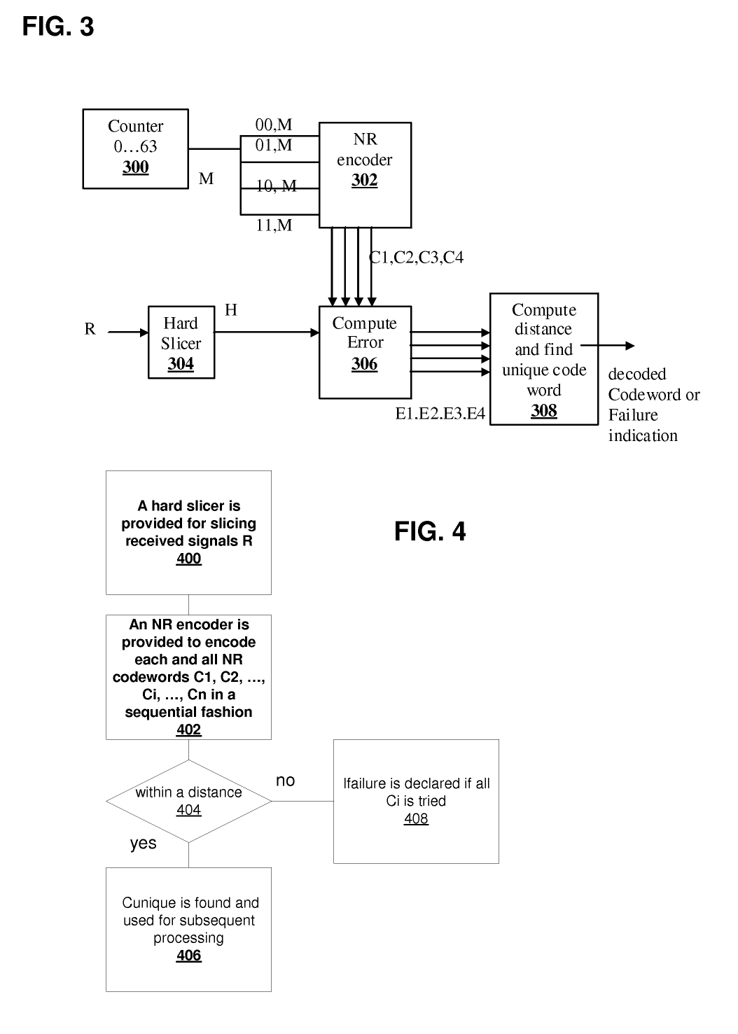

In the architecture of an embodiment, a clock that is 8 times the symbol rate is used. Since in our preferred embodiment each NR code word is QAM modulated the 16 bits correspond to 8 symbols. Hence to complete the decoding of a NR code word is achieved in 8×8=64 clock cycles. Since there are a total of 256 code words to compare with, 4 comparisons are performed in parallel and hence can complete the decoding in 64 clock cycles. The architecture with a parallelization of 4 is showing in FIG. 3.

FIG. 3 is an architecture with a parallelization of the present invention. The counter 300 counts 0 to 63. The four parallel messages differing only in their respective Most Significant Bits, i.e. bits x7 and x6 is defined and processed parallely. Hence the encoder 302 can share the circuitry involving x5 to x0 and need extra circuitry only for the parts involving x7 and x6. The error words E1 to E4 are computed in parallel and parallel circuits are employed to find the unique code word.

FIG. 4 is a flowchart of the present invention. A hard slicer is provided for slicing received signals or a derived signal from the received signal R (Step 400). An NR encoder is provided to encode each and all NR code words C₁, C₂, . . . , Cᵢ, . . . , Cₙ in a sequential fashion (Step 402). The sliced, received signal H is compared with one the Cs e.g. Cᵢ. A determination is made as to whether a distance associated with the code word is within a predetermined value (Step 404). If the value is within the distance, C_{unique} is found and used for subsequent processing (Step 406). If the value is outside the distance, failure is declared if all Cᵢ is tried respectively (Step 408).

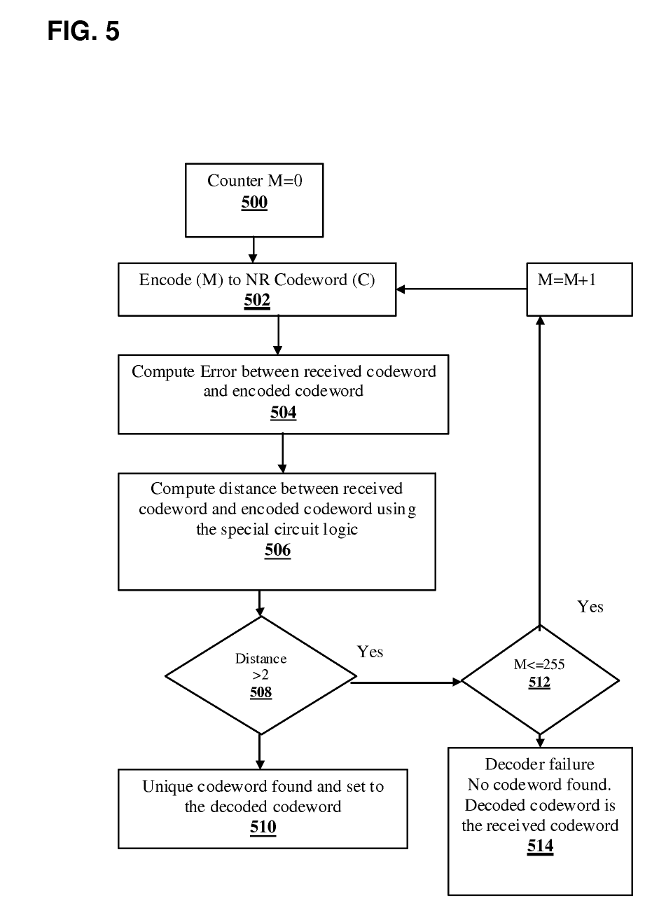

FIG. 5 is a second flowchart of the present invention. Counter is set to zero, M=0 (Step 500). Encode (M) to NR Code word (C) (Step 502). Compute Error between received code word and encoded code word (Step 504). Compute distance between received code word and encoded code word using the special circuit logic (Step 506). Determine whether the Distance is greater than 2 (Distance>2) (Step 508). If not true, a Unique code word found and set as the decoded code word (Step 510). Otherwise, determine whether counter value M is less or equal to 255 (M<=255) (Step 512). If less or equal to 255, M is added by one and reverts back to Step 502. Otherwise, Decoder failure occurs and No code word is found. Decoded code word is the received code word (Step 514).

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method comprising the steps of:
providing a slicer for slicing a signal;
providing an encoder to encode data/messages to a code word among a predetermined number of code words; and
determining a distance associated with the code word.

2. The method of claim 1 further comprising computing the distance associated with a known code word, or finding a unique code word.

3. The method of claim 1, wherein the code word comprises a Nordstrom Robinson (NR) code word.

4. The method of claim 1, wherein the slicer is hardware based.

5. A decoder comprising:
means for slicing a signal;
means for encoding a code word among a predetermined number of code words; and
means for determining a distance associated with the code word.

6. The decoder of claim 5 further comprising means for computing the distance associated with a known coding system, or means for finding a unique code word.

7. The decoder of claim 5, wherein the code word comprises a Nordstrom Robinson (NR) code word.

8. The decoder of claim 5, wherein the slicer is hardware based.

9. A receiver comprising:
a decoder comprising:
means for slicing a signal;
means for encoding data/messages to a code word among a predetermined number of code words; and
means for determining a distance associated with the code word.

10. The receiver of claim 9 further comprising means for computing the distance associated with a known coding system, or means for finding a unique code word.

11. The receiver of claim 9, wherein the code word comprises a Nordstrom Robinson (NR) code word.

12. The receiver of claim 9, wherein the slicer is hardware based.
